(19) United States
(12) Patent Application Publication
(10) Pub. No.: US 2022/0071004 A1
(43) Pub. Date: Mar. 3, 2022

(54) TRANSPARENT CONDUCTIVE FILM AND MANUFACTURING METHOD THEREOF

(71) Applicant: Cambrios Film Solutions Corporation, Tortola (VG)

(72) Inventors: Yung-Cheng Chang, Toufen City (TW); Wei-Ting Tsai, Taoyuan City (TW); Min-Yu Chen, Taoyuan City (TW); Chung-Chin Hsiao, Zhubei City (TW)

(21) Appl. No.: 17/004,186

(22) Filed: Aug. 27, 2020

(51) Int. Cl. H05K 1/02; H05K 1/09; H05K 3/06

(52) U.S. Cl. CPC H05K 1/0296; H05K 1/09; G06F 3/041; H05K 2201/0166; H05K 3/064

(57) ABSTRACT

A transparent conductive film is disclosed. The transparent conductive film includes a substrate; a first silver nanowire layer disposed on the substrate; and a protective layer disposed on the first silver nanowire layer, wherein the protective layer is a patternable photoresist and has an identical pattern as the first silver nanowire layer.

### BACKGROUND

### 1. Field

The present disclosure relates to a transparent conductive film and manufacturing method thereof. More particularly, the present disclosure relates to a transparent conductive film and manufacturing method thereof for preparing a touch panel.

### 2. Description of Related Art

Recently, the application of touch panels is becoming more extensive. More and more electronic products are equipped with touch panels to provide the functions of direct operation or issuing commands for making those electronic products user-friendly. Especially, the demand for flexible touch panels is increasing; therefore, a number of flexible conductive materials with excellent conductivity are being used to replace conventional indium tin oxide (ITO) conductive material.

Silver nanowires having high conductivity and flexibility are an excellent material for touch panels. However, the adhesiveness of the silver nanowires is relatively weak, and the edge of the patterned silver nanowires may be damaged or rendered incomplete when removing the photoresist during the patterning process of the silver nanowires. Thus the yield may be lowered and the cost may be increased.

Accordingly, a novel transparent conductive film and a manufacturing method are required to improve the yield of the patterned silver nanowires.

### SUMMARY

Accordingly, the main object of the present disclosure is to provide a novel transparent conductive film, including: a substrate; a first silver nanowire layer disposed on the substrate; and a protective layer disposed on the first silver nanowire layer; wherein the protective layer includes a patternable photoresist material, and wherein the first silver nanowire layer and the protective layer have an identical pattern.

In one embodiment, the patternable photoresist material includes a positive photoresist material or a negative photoresist material.

In one embodiment, the patternable photoresist material includes at least includes 15 to 30 wt % of an acrylic resin, 65 to 80 wt % of a solvent, 2 to 5 wt % of a photoinitiator, and 0 to 3 wt % of an additive.

In one embodiment, the acrylic resin includes a monomer, an oligomer, and an alkali-soluble resin, wherein the monomer is at least one selected from a group consisting of an aliphatic polyol compound, unsaturated carboxylic acid with acrylate, and a mixture thereof; the oligomer is at least one selected from a group consisting of a urethane acrylate oligomer, an epoxy acrylate oligomer, a polyester acrylate oligomer, and a mixture thereof; and the alkali-soluble resin is at least one selected from a group consisting of a resin with unsaturated substituents, a resin with phenyl group, a resin with carboxyl group, and a mixture thereof.

In one embodiment, the solvent is at least one selected from a group consisting of acetone, methyl ethyl ketone, cyclohexane, propylene glycol methyl ether acetate, propylene glycol methyl ether, ethyl acetate, ethylene dichloride, tetrahydrofuran, toluene, and ether.

In one embodiment, the additive is at least one selected from a group consisting of a leveling agent, a coloring agent, an ultraviolet absorber, a photosensitizer, and a photoluminescence agent.

In one embodiment, a thickness of the protective layer is 0.2 to 2 μm.

In one embodiment, a transmittance of the transparent conductive film to visible light (e.g., wavelength between about 400 nm and 700 nm) is greater than 90%.

In one embodiment, a resistance of the transparent conductive film is 5 to 100 ohm.

In one embodiment, the substrate includes a display area and a non-display area, wherein the first silver nanowire layer is disposed in the display area.

In one embodiment, the transparent conductive film further includes an electric circuit disposed in the non-display area of the substrate, wherein the electric circuit is electrically connected to the first silver nanowire layer.

In one embodiment, the transparent conductive film further includes a second silver nanowire layer disposed in the non-display area of the substrate, wherein the electric circuit and the second silver nanowire layer overlap and have an identical pattern.

In one embodiment, the second silver nanowire layer is disposed between the substrate and the electric circuit or disposed on the electric circuit.

The present disclosure also provides a manufacturing method of a transparent conductive film, which includes the steps of: providing a substrate; forming a first silver nanowire layer on the substrate; forming a protective layer on the first silver nanowire layer; and patterning the protective layer and the first silver nanowire layer; wherein the protective layer includes a patternable photoresist material, and wherein the protective layer and the first silver nanowire layer have an identical pattern.

In one embodiment, the patterning includes patterning the protective layer by an exposure and development process; and removing exposed portions of the first silver nanowire layer by an etching or a non-etching method for patterning the first silver nanowire layer.

In one embodiment, the patterning includes patterning the protective layer and the first silver nanowire layer simultaneously by an exposure and development process.

In one embodiment, the patternable photoresist material includes a positive photoresist material or a negative photoresist material.

In one embodiment, the protective layer at least includes 15 to 30 wt % of an acrylic resin, 65 to 80 wt % of a solvent, 2 to 5 wt % of a photoinitiator, and 0 to 3 wt % of an additive.

In one embodiment, the additive is at least one selected from a group consisting of a leveling agent, a coloring agent, an ultraviolet absorber, a photosensitizer, and a photoluminescence agent.

According to the transparent conductive film and the manufacturing method thereof, the protective layer serves as a photoresist when etching the silver nanowire layer for patterning the silver nanowire layer. Afterward, the protective layer (which served as the photoresist) remains for protecting the silver nanowire layer and improving the yield of the silver nanowire layer.

It should be noted that the term “on” in the specification may be used herein to describe the relative positions between components. For example, a first silver nanowire layer being disposed “on” a substrate includes embodiments in which the two components are formed in direct contact, and may also include embodiments in which additional components may be formed between the first silver nanowire layer and the substrate.

The order of the steps in the manufacturing method of the present disclosure may be altered when needed. One step of the manufacturing method may include multiple steps as long as the same purpose can be achieved.

Furthermore, the terms “first”, “second”, and the like in the specification may be used herein for ease of description and are not related to the numbers or the orders. For example, “first silver nanowire layer” and “second silver nanowire layer” can both be realized as a “silver nanowire layer.”

### BRIEF DESCRIPTION OF THE DRAWINGS

FIG. 1 is a flowchart of the manufacturing method of a transparent conductive film of the first embodiment of the present disclosure;

FIG. 2 is a sectional view of the substrate of the first embodiment of the present disclosure;

FIG. 3 is a sectional view of forming a first silver nanowire layer on the substrate of FIG. 2 of the first embodiment of the present disclosure;

FIG. 4 is a sectional view of forming a protective layer on the structure in FIG. 3 of the first embodiment of the present disclosure;

FIG. 5 is a sectional view of patterning the protective layer of the structure in FIG. 4 of the first embodiment of the present disclosure;

FIG. 6 is a sectional view of etching the first silver nanowire layer of the structure in FIG. 5 of the first embodiment of the present disclosure;

FIG. 7 is a sectional view of the substrate, the first silver nanowire layer, and the protective layer of the second embodiment of the present disclosure;

FIG. 8 is a sectional view of patterning the protective layer and the first silver nanowire layer of the second embodiment of the present disclosure;

FIG. 9 is a top view of the substrate of the third embodiment of the present disclosure;

FIG. 10 is a top view of forming the copper layer on the structure in FIG. 9 of the third embodiment of the present disclosure;

FIG. 11 is a sectional view of forming the copper layer on the structure in FIG. 9 of the third embodiment of the present disclosure;

FIG. 12 is a sectional view of forming the first and second silver nanowire layers on the structure in FIG. 11 of the third embodiment of the present disclosure;

FIG. 13 is a sectional view of patterning the protective layer of the structure in FIG. 12 of the third embodiment of the present disclosure;

FIG. 14 is a sectional view of forming a photoresist on the structure in FIG. 13 of the third embodiment of the present disclosure;

FIG. 15 is a sectional view of the transparent conductive film of the third embodiment of the present disclosure;

FIG. 16 is a top view of the transparent conductive film of the third embodiment of the present disclosure;

FIG. 17 is a sectional view of the structure including the substrate, the first and the second silver nanowire layers, and the protective layer of the fourth embodiment of the present disclosure;

FIG. 18 is a sectional view of patterning the protective layer and the copper layer of the structure in FIG. 17 of the fourth embodiment of the present disclosure;

FIG. 19 is a sectional view of forming a photoresist on the structure in FIG. 18 of the fourth embodiment of the present disclosure;

FIG. 20 is a sectional view of the transparent conductive film of the fourth embodiment of the present disclosure;

FIG. 21 is a sectional view of the structure including the substrate, the patterned copper layer, and the first and the second silver nanowire layer of the fifth embodiment of the present disclosure;

FIG. 22 is a sectional view of forming a protective layer on the structure in FIG. 21 of the fifth embodiment of the present disclosure; and

FIG. 23 is a sectional view of the transparent conductive film of the fifth embodiment of the present disclosure.

### DETAILED DESCRIPTION OF THE PREFERRED EMBODIMENT

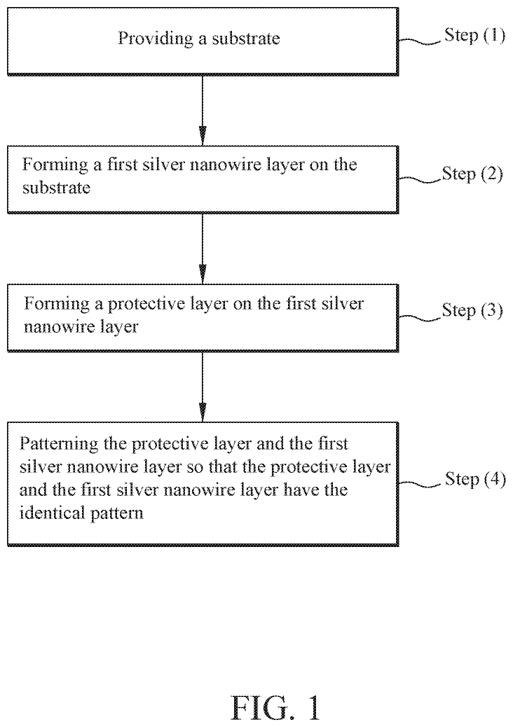

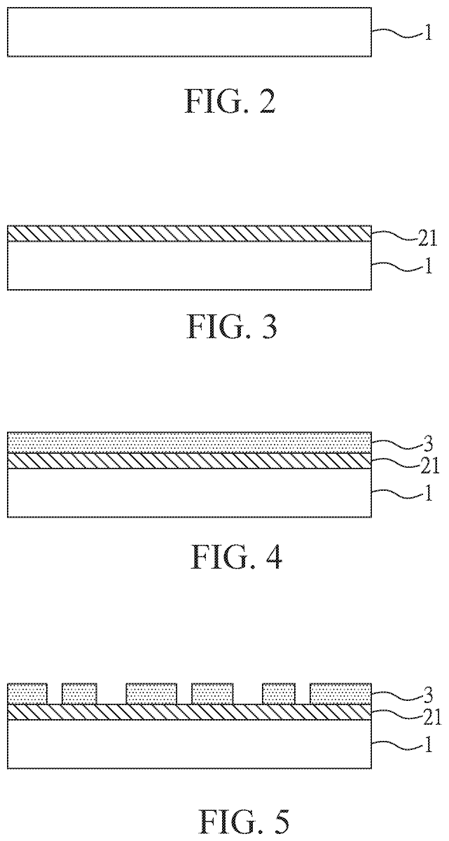

The flow chart illustrated in FIG. 1 shows the preparing method of the transparent conductive film 1000, wherein the preparing method includes the steps illustrated with respect to the flow chart in FIG. 1 and the schematic diagrams in FIG. 2 to FIG. 6.

Firstly, step (1): providing a substrate 1. Referring to FIG. 2, the substrate 1 may be but is not limited to glass, sapphire, polymethyl methacrylate (PMMA), polyvinyl chloride (PVC), polypropylene (PP), polyethylene terephthalate (PET), cyclothin polymer (COP), polyethylene naphthalate (PEN), triacetate cellulose (TAC), polycarbonate (PC), Polystyrene (PS), polyimide (PI), or the like.

Refer to step (2) shown in FIG. 3, which includes forming a first silver nanowire layer 21 on the substrate 1. The first silver nanowire layer 21 includes a plurality of silver nanowires.

Refer to step (3) shown in FIG. 4, which includes forming a protective layer 3 on the first silver nanowire layer 21. The protective layer 3 includes 20 wt % of an acrylic resin, 77 wt % of a solvent, 2.7 wt % of a photoinitiator, and 0.3 wt % of an additive. In the present embodiment, the acrylic resin includes 30 wt % of a monomer, 5 wt % of an oligomer, and 65 wt % of an alkali-soluble resin.

In one embodiment of the present disclosure, the monomer included in the acrylic resin may be at least one selected from a group consisting of an aliphatic polyol compound, unsaturated carboxylic acid with acrylate, and a mixture thereof; the oligomer included in the acrylic resin may be at least one selected from a group consisting of a urethane acrylate oligomer, an epoxy acrylate oligomer, a polyester acrylate oligomer, and a mixture thereof; and the alkali-soluble resin may be at least one selected from a group consisting of a resin with unsaturated substituents, a resin with phenyl group, a resin with carboxyl group, and a mixture thereof. Furthermore, the photoinitiator may be selected from oxime compound, acetophenone compound, phosphine oxide, or a mixture thereof. Also, the additive may be leveling agents such as cationic surfactants, anionic surfactants, nonionic surfactants, zwitterionic surfactants, polysiloxane surfactants, or fluorosurfactants. The additive may also be a coloring agent, an ultraviolet absorber, a photosensitizer, or a photoluminescence agent when needed. The solvent may be acetone, methyl ethyl ketone, cyclohexane, propylene glycol methyl ether acetate, propylene glycol methyl ether, ethyl acetate, ethylene dichloride, tetrahydrofuran, toluene, or ether.

In the present embodiment, the protective layer 3 includes a negative photoresist material. That is, the protective layer 3 includes a photocurable material. In other embodiments, the protective layer 3 may include a positive photoresist material. That is, the protective layer 3 includes a photodegradable material.

Besides, in other embodiments, the protective layer 3 at least includes 15 to 30 wt % of an acrylic resin, 65 to 80 wt % of a solvent, 2 to 5 wt % of a photoinitiator, and 0 to 3 wt % of an additive.

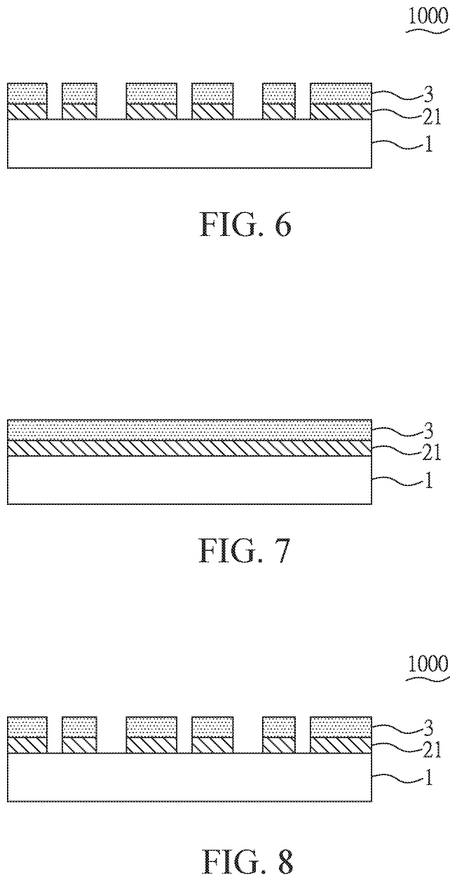

Step (4) includes patterning the protective layer 3 and the first silver nanowire layer 21 so that the protective layer 3 and the first silver nanowire layer 21 have an identical pattern. In the present embodiment, step (4) further includes the step (4-a): patterning the protective layer 3 by an exposure and development process for forming an electrode pattern shown in FIG. 5; and the step (4-b): removing exposed portions of the first silver nanowire layer 21 by an etching method for patterning the first silver nanowire layer 21. The resulting transparent conductive film 1000 is shown in FIG. 6.

In the present embodiment, the etching method in step (4-b) is dry-etching or wet-etching. In other embodiments, however, the exposed portions of the first silver nanowire layer 21 may be removed by non-etching methods such as a development method or a lift-off method.

The protective layer 3 and the first silver nanowire layer 21 prepared in the present embodiment have an identical electrode pattern. After the patterning process, the protective layer 3 remains on the first silver nanowire layer 21 for protecting the first silver nanowire layer 21. Accordingly, damage of the patterned first silver nanowire layer 21 due to removing the photoresist layer may be avoided.

The manufacturing method of the transparent conductive film 1000 of the second embodiment of the present disclosure is similar to that of the first embodiment of the present disclosure. The difference is that the step (4) includes the step (4-1): patterning the protective layer 3 and the first silver nanowire layer 21 simultaneously by an exposure and development process for forming an electrode pattern shown in FIG. 7 to FIG. 8. Specifically, portions of the first silver nanowire layer 21 were washed together with the exposed protective layer 3. Accordingly, the protective layer 3 having the electrode pattern and the first silver nanowire layer 21 having the electrode pattern were formed simultaneously.

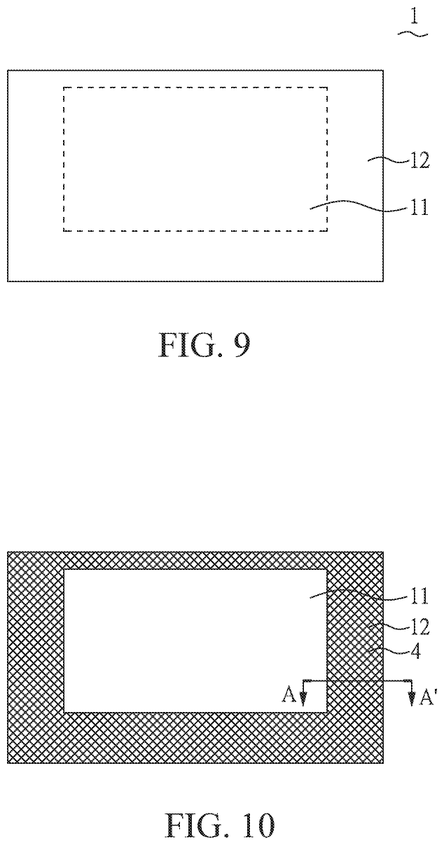

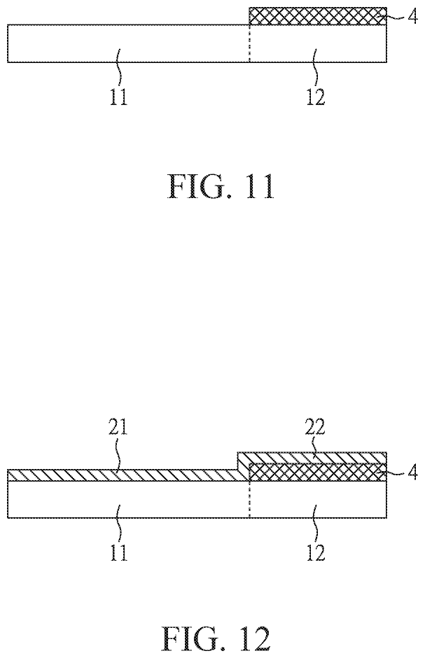

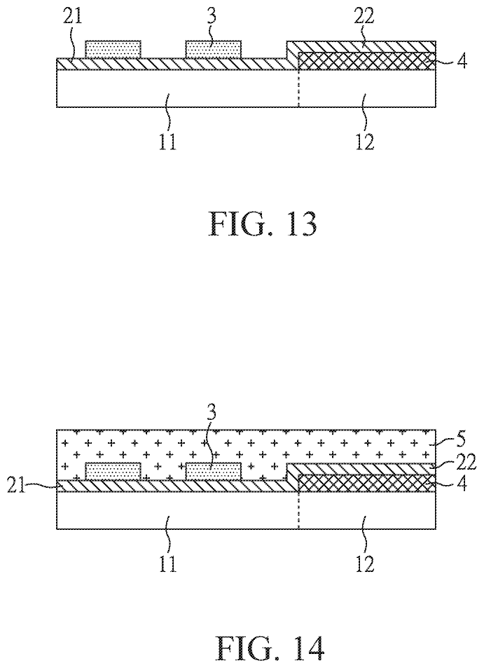

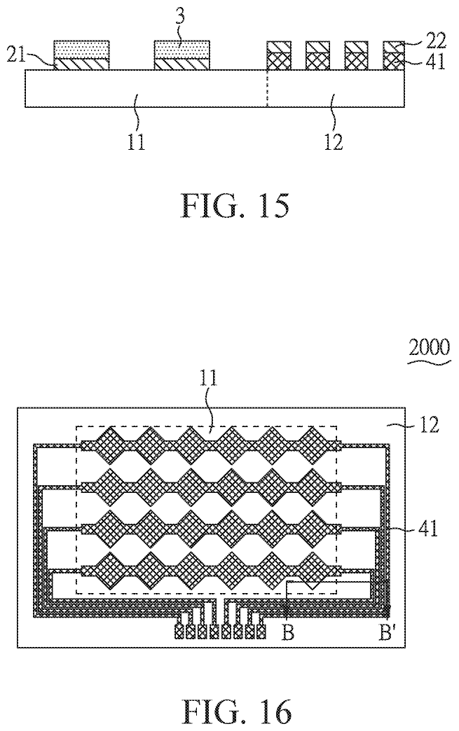

The present disclosure further provides the manufacturing method of the transparent conductive film 2000 of the third embodiment of the present disclosure. The manufacturing process is shown in FIG. 9 to FIG. 16. The manufacturing process of the transparent conductive film 2000 of the present embodiment includes the steps for manufacturing the transparent conductive film 1000 of the first embodiment and other additional steps. First, as shown in FIG. 9, a substrate 1 having a display area 11 and a non-display area 12 is provided (step (1)). Then, as shown in FIG. 10 and FIG. 11, a copper layer 4 is formed on the non-display area 12. Referring to FIG. 12, the silver nanowires are sprayed on the display area 11 of the substrate 1 and on the copper layer 4 on the non-display area 12 of the substrate 1. A first silver nanowire layer 21 (step (2)) is formed on the display area 11 and a second silver nanowire layer 22 is formed on the copper layer 4, which is formed on the non-display area 12. Referring to FIG. 13, a protective layer 3 (step (3)) is formed on the first silver nanowire layer 21 and the second silver nanowire layer 22, then the protective layer 3 is patterned by an exposure and development process so that the protective layer 3 has an electrode pattern (step (4-a)). Please refer to FIG. 14, a photoresist 5 is formed on the first silver nanowire layer 21, the second silver nanowire layer 22, and the patterned protective layer 3. After the photoresist 5 is formed, the copper layer 4 and the second silver nanowire layer 22 on the non-display area 12 are patterned by another exposure and development process to form a plurality of electric circuits 41. During the exposure and development process, the exposed portions of the first silver nanowire layer 21, which are uncovered by the protective layer 3, are removed so that the first silver nanowire layer 21 is patterned (step (4-b)) and has the identical electrode pattern as the protective layer 3. At last, the transparent conductive film 2000 shown in FIG. 15 and FIG. 16 is accomplished.

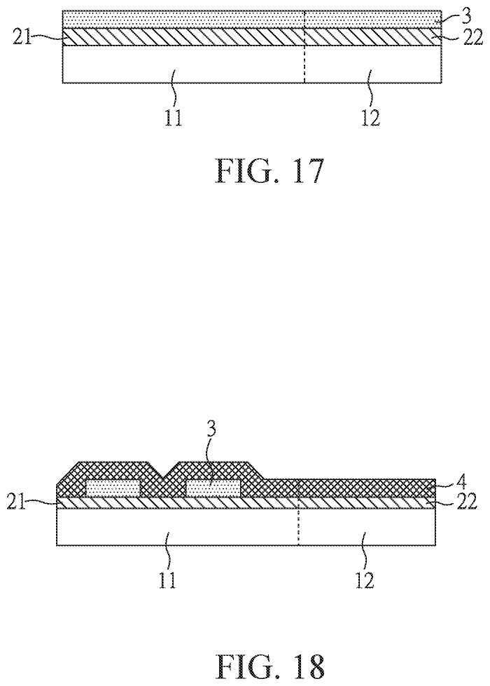

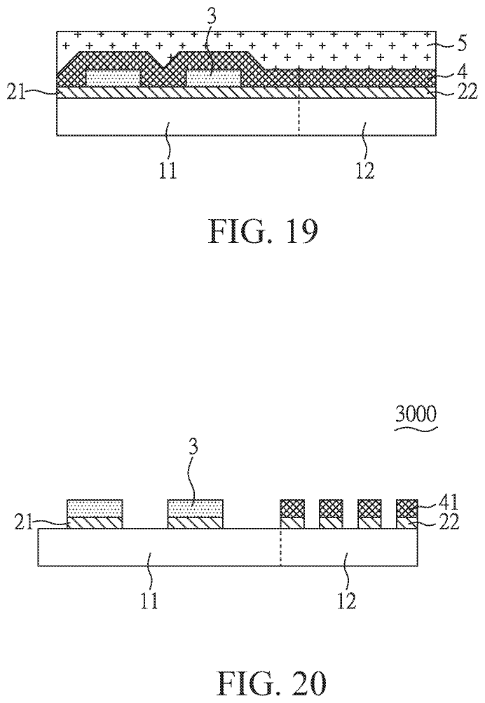

The present disclosure further provides the manufacturing method of the transparent conductive film 3000 of the fourth embodiment of the present disclosure. The manufacturing process is shown in FIG. 17 to FIG. 20. The present embodiment includes the steps for manufacturing the transparent conductive film 1000 of the first embodiment and other steps for forming the transparent conductive film 3000 of the present embodiment. First, as shown in FIG. 17, a laminated structure including a substrate 1, a first silver nanowire layer 21, a second silver nanowire layer 22, and a protective layer 3 is provided (including step (1), step (2), and step (3)). The first silver nanowire layer 21 is formed on the display area 11 of the substrate 1, and the second silver nanowire layer 22 is formed on the non-display area 12 of the substrate 1. As shown in FIG. 18, an exposure and development process is performed for patterning the protective layer 3 (step (4-a)) so that the protective layer 3 may have an electrode pattern. Then, a copper layer 4 is formed on the first silver nanowire layer 21, the second silver nanowire layer 22, and the patterned protective layer 3. Referring to FIG. 19, a photoresist 5 is formed on the copper layer 4, then another exposure and development process is performed so that the copper layer 4 and the second silver nanowire layer 22 on the non-display area 12 were patterned and serve as a plurality of electric circuits 41; and the exposed portions of the first silver nanowire layer 21, uncovered by the protective layer 3, are removed (step (4-b)).

The patterned first silver nanowire layer 21 has an identical electrode pattern as the protective layer 3. The transparent conductive film 3000 shown in FIG. 20 is accomplished.

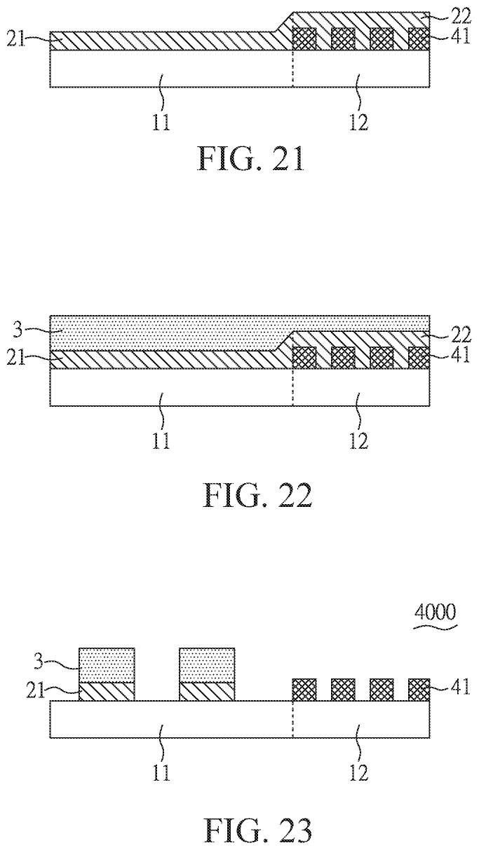

The present disclosure further provides the manufacturing method of the transparent conductive film 4000 of the fifth embodiment of the present disclosure. The manufacturing process is shown in FIG. 21 to FIG. 23.

The present embodiment includes the steps for manufacturing the transparent conductive film 1000 of the second embodiment and other steps for forming the transparent conductive film 4000 of the present embodiment. First, referring to FIG. 21, a substrate 1 having a display area 11 and a non-display area 12 is provided (step (1)). An exposure and development process is performed to form a plurality of copper electric circuits 41 on the non-display area 12. Then, the silver nanowires are sprayed on the display area 11 of the substrate 1 and the electric circuits 41 for forming a first silver nanowire layer 21 (step (2)) on the display area 11 and forming a second silver nanowire layer 22 on the electric circuits 41. As shown in FIG. 22, a protective layer 3 is formed on the first silver nanowire layer 21 and the second silver nanowire layer 22 (step (3)). Another exposure and development process is performed for patterning the protective layer 3 and the first silver nanowire layer 21 simultaneously so that the protective layer 3 and the first silver nanowire layer 21 may have an identical electrode pattern (step (4-1)). On the other hand, the protective layer 3 on the non-display area 12 and the second silver nanowire layer 22 are removed completely to expose the electric circuits 41. Accordingly, the transparent conductive film 4000 shown in FIG. 23 was accomplished. The above disclosure is related to the detailed technical contents and inventive features thereof. People skilled in the art may proceed with a variety of modifications and replacements based on the disclosures and suggestions of the disclosure as described without departing from the characteristics thereof. Nevertheless, although such modifications and replacements are not fully disclosed in the above descriptions, they have substantially been covered in the following claims as appended.

What is claimed is:

1. A transparent conductive film, comprising:
a substrate;
a first silver nanowire layer disposed on the substrate; and
a protective layer disposed on the first silver nanowire layer;
wherein the protective layer comprises a patternable photoresist material, and wherein the first silver nanowire layer and the protective layer have an identical pattern.

2. The transparent conductive film as claimed in claim 1, wherein the patternable photoresist material is a positive photoresist material or a negative photoresist material.

3. The transparent conductive film as claimed in claim 1, wherein the patternable photoresist material comprises 15 to 30 wt % of an acrylic resin, 65 to 80 wt % of a solvent, 2 to 5 wt % of a photoinitiator, and 0 to 3 wt % of an additive.

4. The transparent conductive film as claimed in claim 3, wherein the acrylic resin comprises a monomer, an oligomer, and an alkali-soluble resin, wherein the monomer is at least one selected from a group consisting of an aliphatic polyol compound, unsaturated carboxylic acid with acrylate, and a mixture thereof; the oligomer is at least one selected from a group consisting of a urethane acrylate oligomer, an epoxy acrylate oligomer, a polyester acrylate oligomer, and a mixture thereof; and the alkali-soluble resin is at least one selected from a group consisting of a resin with unsaturated substituents, a resin with phenyl group, a resin with carboxyl group, and a mixture thereof.

5. The transparent conductive film as claimed in claim 3, wherein the solvent is at least one selected from a group consisting of acetone, methyl ethyl ketone, cyclohexane, propylene glycol methyl ether acetate, propylene glycol methyl ether, ethyl acetate, ethylene dichloride, tetrahydrofuran, toluene, and ether.

6. The transparent conductive film as claimed in claim 3, wherein the additive is at least one selected from a group consisting of a leveling agent, a coloring agent, an ultraviolet absorber, a photosensitizer, and a photoluminescence agent.

7. The transparent conductive film as claimed in claim 1, wherein a thickness of the protective layer is 0.2 to 2 μm.

8. The transparent conductive film as claimed in claim 1, wherein a transmittance of the transparent conductive film is greater than 90%.

9. The transparent conductive film as claimed in claim 1, wherein a resistance of the transparent conductive film is 5 to 100 ohm.

10. The transparent conductive film as claimed in claim 1, wherein the substrate comprises a display area and a non-display area, wherein the first silver nanowire layer is disposed in the display area.

11. The transparent conductive film as claimed in claim 10, further comprising an electric circuit disposed in the non-display area of the substrate, wherein the electric circuit is electrically connected to the first silver nanowire layer.

12. The transparent conductive film as claimed in claim 11, further comprising a second silver nanowire layer disposed in the non-display area of the substrate, wherein the electric circuit and the second silver nanowire layer overlap and have an identical pattern.

13. The transparent conductive film as claimed in claim 12, wherein the second silver nanowire layer is disposed between the substrate and the electric circuit or disposed on the electric circuit.

14. A manufacturing method of a transparent conductive film, comprising the steps of:
providing a substrate;
forming a first silver nanowire layer on the substrate;
forming a protective layer on the first silver nanowire layer; and
patterning the protective layer and the first silver nanowire layer;
wherein the protective layer comprises a patternable photoresist material, and wherein the protective layer and the first silver nanowire layer have an identical pattern.

15. The manufacturing method as claimed in claim 14, wherein the patterning comprises:
patterning the protective layer by an exposure and development process; and
removing exposed portions of the first silver nanowire layer by an etching or a non-etching method for patterning the first silver nanowire layer.

16. The manufacturing method as claimed in claim 14, wherein the patterning comprises patterning the protective layer and the first silver nanowire layer simultaneously by an exposure and development process.

17. The manufacturing method as claimed in claim 14, wherein the patternable photoresist material comprises a positive photoresist material or a negative photoresist material.

18. The manufacturing method as claimed in claim 14, wherein the protective layer at least comprises 15 to 30 wt % of an acrylic resin, 65 to 80 wt % of a solvent, 2 to 5 wt % of a photoinitiator, and 0 to 3 wt % of an additive.
